(19) United States
(12) Patent Application Publication
(10) Pub. No.: US 2015/0041888 A1
(43) Pub. Date: Feb. 12, 2015

(54) SEMICONDUCTOR DEVICE INCLUDING BURIED BIT LINE, AND ELECTRONIC DEVICE USING THE SAME

(71) Applicant: SK HYNIX INC., Icheon (KR)

(72) Inventor: Seung Hwan KIM, Seoul (KR)

(73) Assignee: SK HYNIX INC., Icheon (KR)

(21) Appl. No.: 14/139,324

(22) Filed: Dec. 23, 2013

(30) Foreign Application Priority Data
Aug. 12, 2013 (KR) 10-2013-0095424

(51) Int. Cl. H01L 29/78

(52) U.S. Cl. CPC H01L 29/7827
USPC 257/330

(57) ABSTRACT

A semiconductor device includes: an active region defined by a device isolation film, an upper portion of which is divided into a first active pillar and a second active pillar; a first gate formed to proceed between the first active pillar and the second active pillar so as to obliquely cross the active region, and formed to contact the first active pillar; a second gate formed to proceed between the first active pillar and the second active pillar so as to obliquely cross the active region, and formed to cross the second active pillar; a conductive line formed below the first gate and the second gate, and commonly coupled to the first pillar and the second pillar; and an insulation film formed to enclose the conductive line within the active region.

### CROSS-REFERENCE TO RELATED APPLICATION

The priority of Korean patent application No. 10-2013-0095424 filed on 12 Aug. 2013, the disclosure of which is hereby incorporated by reference in its entirety, is claimed.

### BACKGROUND

Embodiments relate to a semiconductor device, and more particularly to a semiconductor device in which a buried bit line (BBL) is applicable to a highly integrated device, including but not limited to a 6F² structure, so as to reduce parasitic capacitance of a bit line.

Semiconductor devices are designed to be used for predetermined purposes by implanting impurities or depositing a new material at a predetermined region of a silicon wafer. The semiconductor memory device includes a large number of elements to carry out given purposes, for example, transistors, capacitors, resistors, and the like. Individual elements are interconnected through a conductive layer so that data or signals are communicated therebetween.

With the increasing development in technologies for manufacturing semiconductor devices, many people are conducting intensive research into a method for forming more chips on one wafer by increasing the integration degree of semiconductor devices. Therefore, in order to increase the integration degree of such semiconductor devices, a minimum feature size required for the design rules of semiconductor devices becomes smaller.

However, as the integration degree of the semiconductor device is gradually increased, parasitic capacitance of a bit line is gradually increased.

### SUMMARY

Various embodiments are directed to providing a semiconductor device including a buried bit line (BBL), and an electronic device including the same that substantially obviate one or more problems due to limitations and disadvantages of the related art.

An embodiment relates to a highly integrated semiconductor device, e.g., a 6F² structure, employing a buried bit line (BBL) with low parasitic capacitance.

In accordance with an aspect of the embodiment, a semiconductor device includes: an active region defined by a device isolation film having an upper portion divided into a first active pillar and a second active pillar; a first gate extending between the first active pillar and the second active pillar to cross the active region; the first gate coupled to the first active pillar; a second gate extending between the first active pillar and the second active pillar to cross the active region, the second gate coupled to the second active pillar; a conductive linepositioned under the first gate and the second gate, the conductive line commonly coupled to the first pillar and the second pillar; and an insulation film enclosing the conductive line within the active region.

In accordance with another aspect of the embodiment, a semiconductor device includes: an active region formed to include a first active pillar and a second active pillar; first and second gates between the first active pillar and the active pillar and arranged across the active region; a bit line positioned under the first gate and the second gate, and arranged across the active region; and an insulation film enclosing the bit line within the active region.

In accordance with another aspect of the embodiment, an electronic device includes: a memory device configured to store data and read the stored data in response to a data input/output (I/O) control signal; and a memory controller configured to generate the data I/O control signal, and control data I/O operations of the memory device. The memory device includes: an active region including a first active pillar and a second active pillar; first and second gates extending between the first active pillar and the active pillar and across the active region; a conductive line positioned under the first gate and the second gate, and arranged across the active region; and an insulation film enclosing the conductive line within the active region.

In accordance with another aspect of the embodiment, an semiconductor device includes: first and second active pillars; a bit line provided between the first and the second active pillars and commonly coupled to the first and the second active pillars; a first gate provided above the bit line and coupled to the first active pillar; and a second gate provided above the bit line and coupled to the second active pillar.

The semiconductor device further comprising: first and second storage node contacts provided above the respective first and the second active pillars.

It is to be understood that both the foregoing general description and the following detailed description of embodiments are exemplary and explanatory and are not restrictive.

### BRIEF DESCRIPTION OF THE DRAWINGS

FIG. 1 is a plan view illustrating a semiconductor device according to an embodiment.

FIG. 2A is a cross-sectional view illustrating the semiconductor device taken along the line A-A′ of FIG. 1, and FIG. 2B is a cross-sectional view illustrating the semiconductor device taken along the line B-B′ of FIG. 1.

FIG. 3 is a cross-sectional view illustrating air-gaps formed between buried bit lines (BBLs) of FIG. 1.

FIGS. 4A to 17C are plan views and cross-sectional views illustrating a method for forming the semiconductor device shown in FIG. 2.

FIGS. 18A and 19C are plan views and cross-sectional views illustrating a method for forming a buried bit line (BBL) according to an embodiment.

FIGS. 20A to 24C are plan views and cross-sectional views illustrating a method for forming a buried bit line (BBL) according to another embodiment.

FIG. 25 is a block diagram illustrating a memory device according to an embodiment.

FIG. 26 is a block diagram illustrating an electronic device including a memory device according to an embodiment.

FIGS. 27A and 27B illustrate various examples of the memory device shown in FIG. 26.

FIG. 28 is a block diagram illustrating a memory system according to another embodiment.

FIG. 29 is a block diagram illustrating an electronic device according to another embodiment.

FIG. 30 is a block diagram illustrating an electronic device according to another embodiment.

### DESCRIPTION OF EMBODIMENTS

Reference will now be made in detail to certain embodiments, examples of which are illustrated in the accompanying drawings. Wherever possible, the same reference numbers will be used throughout the drawings to refer to the same or like parts. In the following description, a detailed description of related known configurations or functions incorporated herein will be omitted.

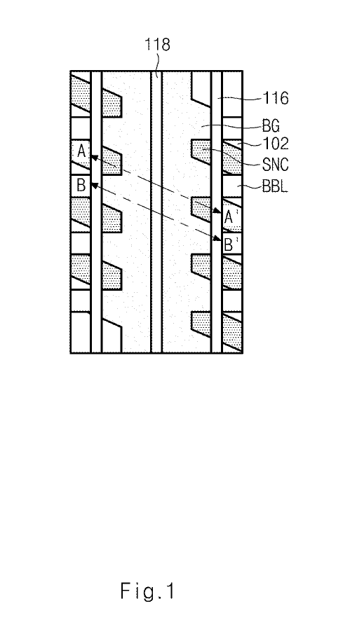

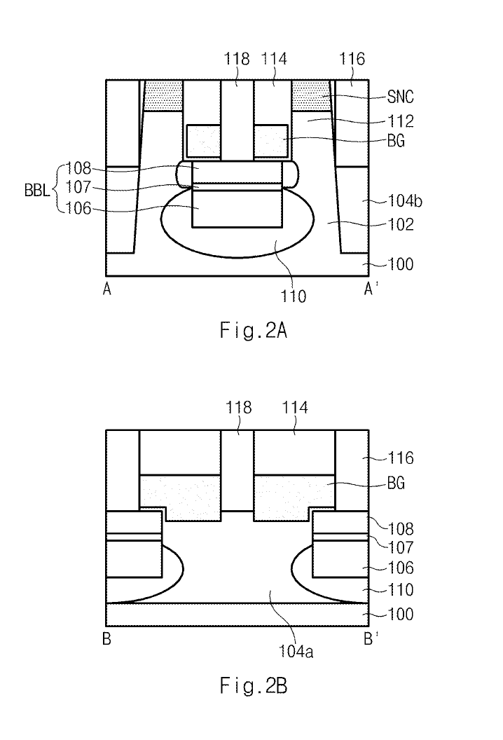

FIG. 1 is a plan view illustrating a semiconductor device according to an embodiment. FIG. 2A is a cross-sectional view illustrating the semiconductor device taken along the line A-A′ of FIG. 1, and FIG. 2B is a cross-sectional view illustrating the semiconductor device taken along the line B-B′ of FIG. 1.

Referring to FIGS. 1, 2A, and 2B, an active region 102 formed by etching a semiconductor substrate 100 is isolated by insulation films (104a, 104b, 116), and a buried gate (BG) is formed to obliquely cross a buried bit line (BBL). In this case, if the semiconductor substrate 100 is etched in a line type and is cut (or isolated) by a cutting mask in units of a predetermined length, the active region 102 may be formed. An upper portion of the active region 102 may share buried bit lines (BBLs), and may be divided into a pair of active pillars 112 each having a vertical channel region. A storage node contact (SNC) is formed over each of the active pillars 112. The storage node contact (SNC) may include doped polysilicon.

The buried bit line (BBL) may be formed to vertically cross a buried gate (BG) and be located below the BG. The BBL may include a stacked structure of a metal layer (for example, tungsten (W)) 106, a barrier metal layer (for example, titanium (Ti), titanium nitride (TiN), etc.) 107, and a polysilicon layer 108. Alternatively, the BBL may be formed of a metal layer only. As described above, according to the embodiment, the buried bit line (BBL) is buried in the active region 102 in a manner that the BBL is located below the buried gate (BG), such that a distance between the BBL and a storage node is sufficiently elongated and therefore parasitic capacitance between the BBL and the storage node is greatly reduced. In addition, the BBL is buried in the active region 102 under the condition that an insulation film 110 is formed as a bulb shape enclosing the BBL, such that parasitic capacitance is prevented from occurring between the BBL and the semiconductor substrate 100. Here, the insulation film 110 may include an oxide film, and may be formed to enclose a specific part not contacting a bit-line junction region on a bit line.

The buried gate (BG) is formed to vertically cross the buried bit line (BBL), and is extended to between an adjacent pair of active pillars 112 arranged along the direction of the buried gate (BG), such that the buried gate (BG) can enclose three sides of the active pillars 112. That is, a vertical channel may be formed over three sidewalls of the active pillars 112. The buried gate (BG) may extend to near a top surface of each BBL with a specific region interposed between the BBLs blocked and parasitic capacitance between the BBLs reduced. A capping insulation film 114 for insulating the BG may be formed over the BG, and an insulation film 118 for isolating the BGs may be formed between the BGs sharing the buried bit lines (BBL). Here, the insulation films (114, 118) may include an oxide film.

The BG shown in FIG. 1 which is formed between the insulation films (116, 118) is an example and should not be construed as being restrictive. In addition, in FIG. 1, the capping insulation film 114 formed over the BG is not shown to simplify the drawing.

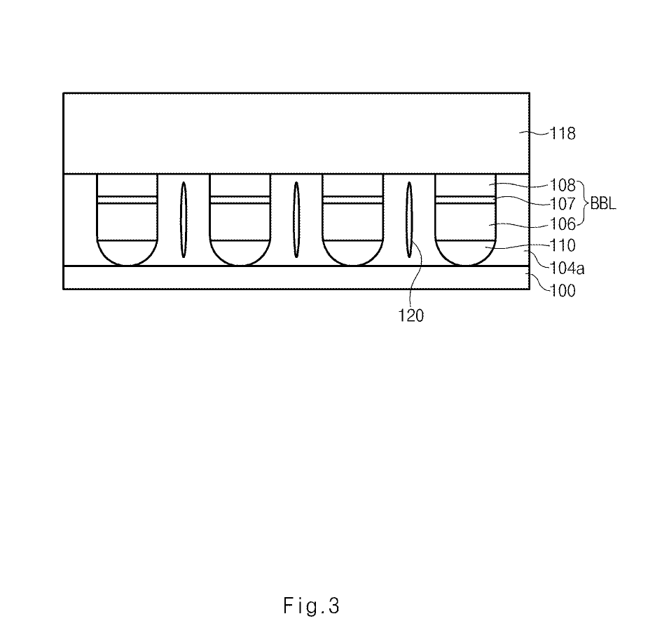

FIG. 3 is a cross-sectional view illustrating a semiconductor device according to another embodiment. In more detail, FIG. 3 is a cross-sectional view illustrating air-gaps 120 formed between the buried bit lines (BBLs) in the semiconductor device.

At least one air-gap 120 may be formed between the BBLs as shown in FIG. 3, such that parasitic capacitance between the BBLs can be significantly reduced.

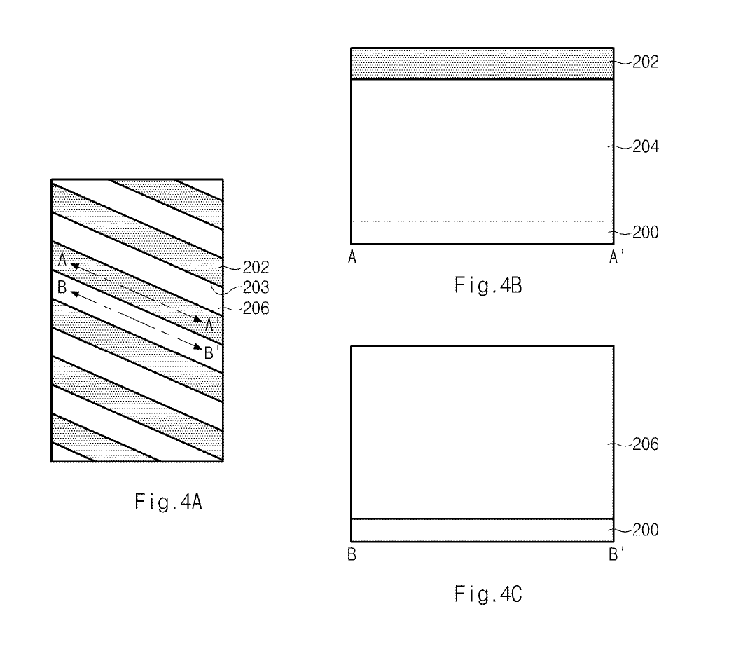

FIGS. 4A to 17C are cross-sectional views illustrating a method for forming the semiconductor device shown in FIGS. 1, 2A, and 2B. FIGS. 4A to 17A are plan views, FIGS. 4B to 17B are cross-sectional views illustrating the semiconductor device taken along the lines A-A′ of the plan views of FIGS. 4A to 17A, and FIGS. 4C to 17C are cross-sectional views illustrating the semiconductor device taken along the lines B-B′ of the plan views of FIGS. 4A to 17A.

Referring to FIGS. 4A-4C, a pad oxide film (not shown) and a pad nitride film (not shown) may be formed over a semiconductor substrate 200, and a hard mask layer (not shown) may be formed over the pad nitride film. In this case, the hard mask layer may include a nitride film.

Subsequently, after an ISO (Isolation) mask pattern (not shown) defining a line-type active region is formed over the hard mask layer, the hard mask layer is etched using the ISO mask pattern as an etch mask, resulting in formation of the hard mask pattern 202. Here, the ISO mask pattern may be formed through a Spacer Pattern Technology (SPT) process.

Subsequently, the pad oxide film, the pad nitride film, and the semiconductor substrate 200 are sequentially etched using the hard mask pattern 202 as an etch mask, such that a device-isolation trench 203 defining a line-type active region 204 is formed. In this case, the active region 204 may be formed to cross a bit line. A gate (word line) is formed in a subsequent process.

After that, a sidewall insulation film (not shown) may be formed at a sidewall of the device-isolation trench. The sidewall insulation film may include a wall oxide material such as an oxide film, and the wall oxide material may be deposited at a sidewall of the device-isolation trench, or may be formed at a sidewall of the device-isolation trench through a dry or wet oxidation process.

Subsequently, a device-isolation insulation film fills in the device-isolation trench. The device-isolation insulation film is planarized until the hard mask pattern 202 is exposed, such that a device isolation film 206 is formed to define a line-type active region 204. In this case, the device isolation film 206 may include a Spin On Dielectric (SOD) material having superior gapfill characteristics, or a High Density Plasma (HDP) oxide film.

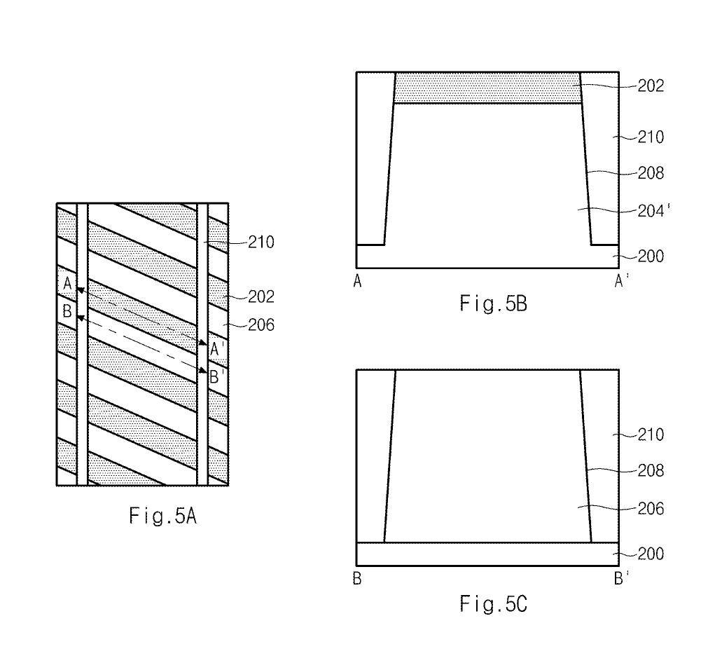

Referring to FIGS. 5A-5C, the hard mask pattern 202 and the device isolation film 206 are etched as a line type using an ISO cutting mask configured to cut (or isolate) the active region 204 in units of a predetermined length, resulting in formation of a device-isolation trench 208.

In this case, the device-isolation trench 208 may be formed as a line type in a manner that the device-isolation trench 208 is arranged in the same direction as the buried gate (BG) to be formed in a subsequent process. Subsequently, a sidewall insulation film (not shown) may be formed at a sidewall of the device-isolation trench 208. Here, the sidewall insulation film may include a wall oxide film.

The insulation film is formed to bury the device-isolation trench 208 and then planarized, such that a device isolation film 210 for defining the isolated active region 204′ is formed at a predetermined interval. Here, the device isolation film 210 may include a nitride film.

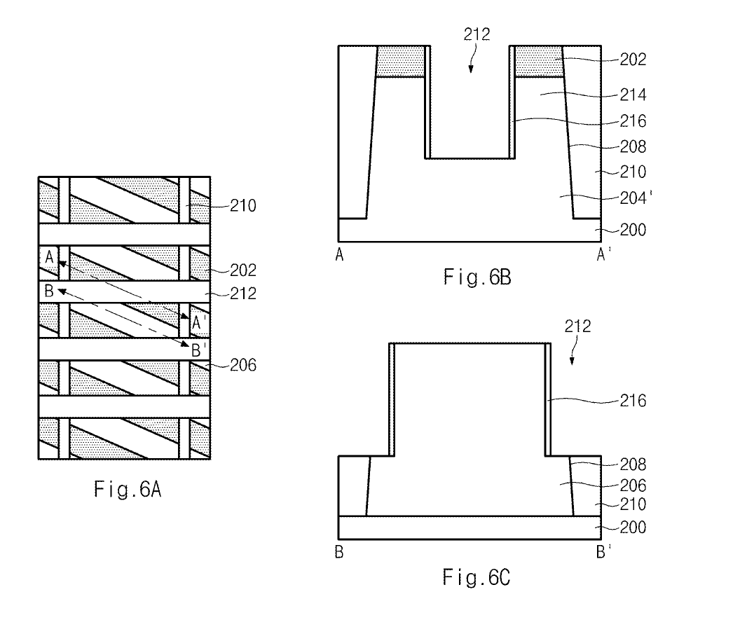

Referring to FIGS. 6A-6C, a hard mask pattern 202, device isolation films (206, 210), and the active region 204′ are etched using a mask (i.e., a bit-line mask) defining a bit-line region, such that a trench 212 for the bit line is formed. An upper portion of the active region 204′ is divided into a pair of active pillars 214 by the bit-line trench 212.

Thereafter, a spacer 216 is formed at a sidewall of the bit-line trench 212. For example, after an insulation film for a spacer is formed at a sidewall and bottom surface of the bit-line trench 212, the spacer insulation film is etched back, resulting in formation of a spacer 216. Here, the spacer 216 may include a nitride film.

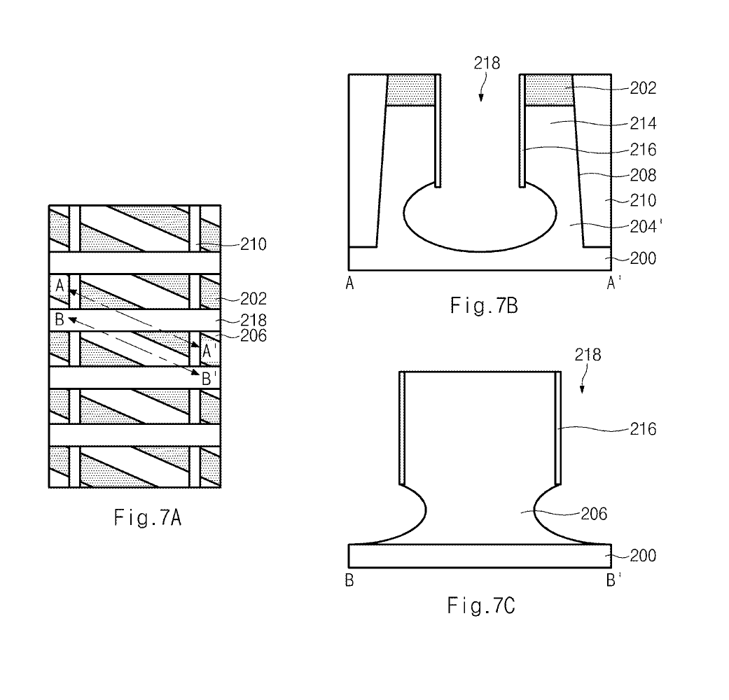

Referring to FIGS. 7A-7C, not only the active region 204′ exposed at a bottom surface of the bit-line trench 212, but also the device isolation films (206, 210) are further etched as a bulb shape using the spacer 216 as a barrier film, resulting in formation of a trench 218.

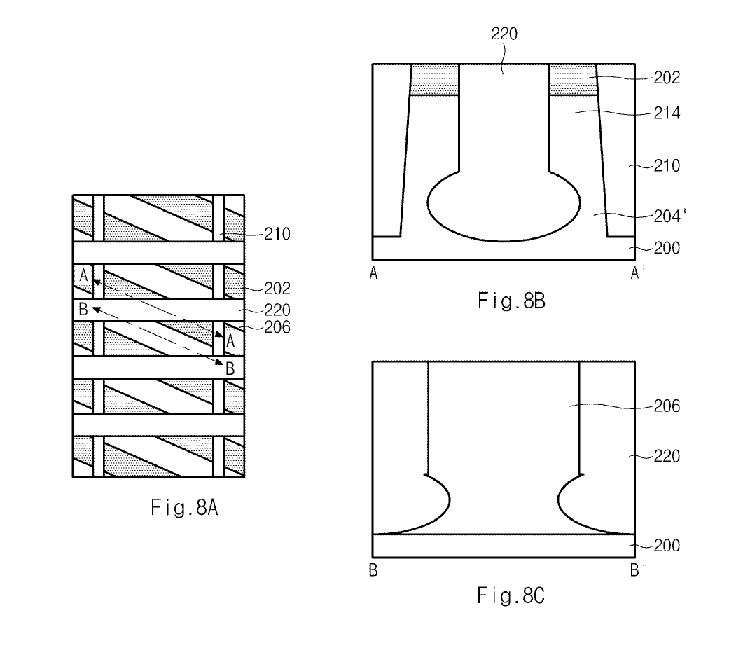

Referring to FIGS. 8A-8C, after the spacer 216 is removed through, for example, a strip process, an insulation film 220 is formed to bury the trench 218. Here, the insulation film 220 may include an oxide film. Subsequently, after a thermal annealing (TA) process is applied to the insulation film 220, the insulation film 220 is etched and planarized until the hard mask pattern 202 is exposed.

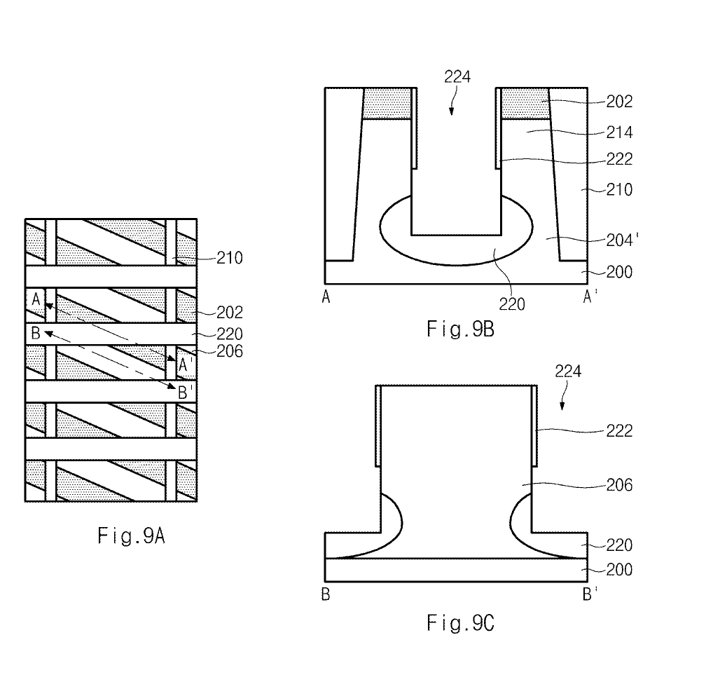

Referring to FIGS. 9A-9C, after the insulation film 220 is etched to a predetermined depth so as to form a trench (not shown), a spacer 222 is formed at a sidewall of the trench. In this case, the etched depth of the above trench may be less than that of the trench 212 shown in FIG. 6.

Subsequently, the insulation film 220 exposed at a bottom surface of the trench is further etched using the spacer 222 as a barrier film, resulting in formation of a trench 224. A silicon substrate may be exposed at a sidewall of a lower portion of the trench 224.

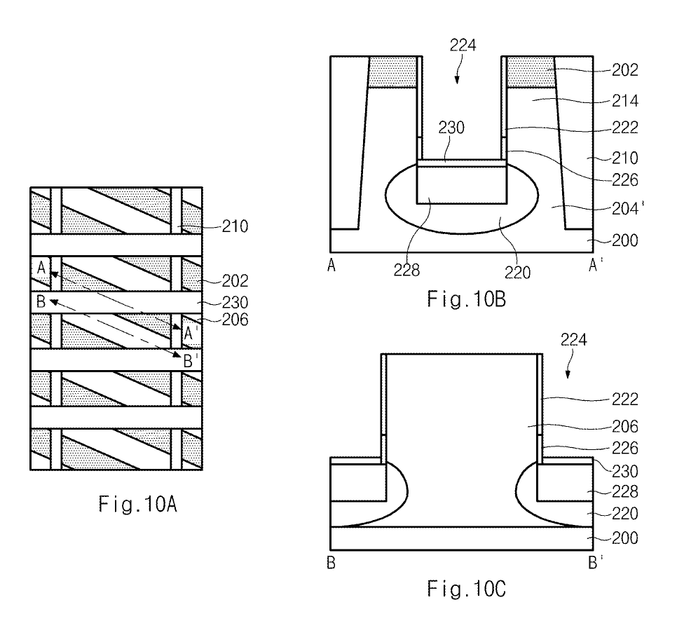

Referring to FIGS. 10A-10C, the exposed sidewall of the active pillar 214 is oxidized using a selective oxidation process, resulting in formation of a sidewall oxide film 226.

Subsequently, after a metal layer (not shown) is formed to bury the trench 224, the metal layer is etched back, so that a lower BBL (Buried Bit Line) 228 is formed at a lower portion of the trench 224. In this case, the metal layer may include tungsten (W), and the lower BBL 228 may be buried in the bulb-shaped insulation film 220.

After that, a barrier metal film 230 is deposited over the lower BBL 228. Here, the barrier metal layer 230 may include titanium (Ti) and titanium nitride (TiN).

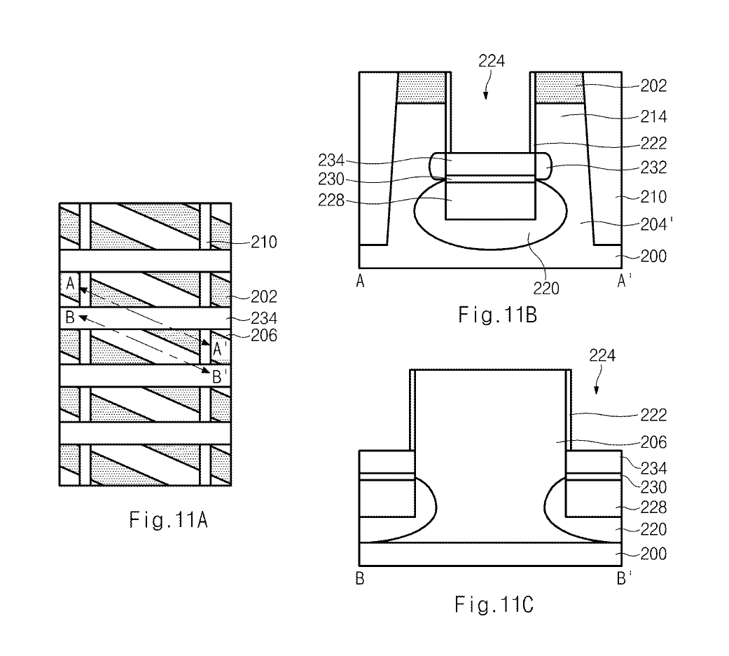

Referring to FIGS. 11A-11C, after the sidewall oxide film 226 formed at a sidewall of the active pillar 214 is removed, the silicon substrate is grown using a Selective Epitaxial Growth (SEG) process, such that a growth layer (not shown) is formed over the barrier metal layer 230.

Subsequently, N-type impurity (for example, As) is implanted into the growth layer and a Rapid Thermal Annealing (RTA) process is then applied thereto, such that the N-type impurity is diffused into the active pillar 214, resulting in formation of a bit-line junction region 232. After that, the impurity-implanted growth layer is etched back. Then, an upper BBL 234 is formed over the barrier metal layer 230.

Although the embodiment has exemplarily disclosed that a growth layer for forming the upper BBL 234 is formed and impurity is then implanted into the growth layer for convenience of description, the method of forming the bit-line junction region 232 is not limited thereto. For another example, a doped polysilicon material may be deposited over the trench 224 in a manner that the trench 224 is filled with the doped polysilicon.

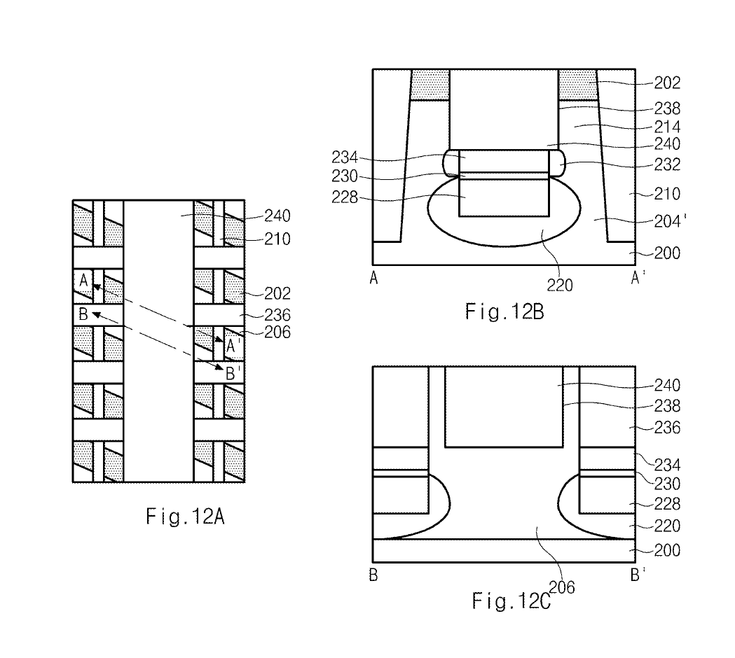

Referring to FIGS. 12A-12C, after the spacer 222 is removed, a capping insulation film 236 is formed over the upper BBL 234 so as to bury the trench 224, and is then planarized. Here, the capping insulation film 236 may include an oxide film.

The hard mask pattern 202, the device isolation film 206, and the capping insulation film 236 are etched using a gate mask defining the buried gate (BG) region until the upper BBL 234 is exposed, such that a trench 238 for a gate is formed. Subsequently, an insulation film 240 may be formed to bury the gate trench 238. Here, the insulation film 240 may include an oxide film.

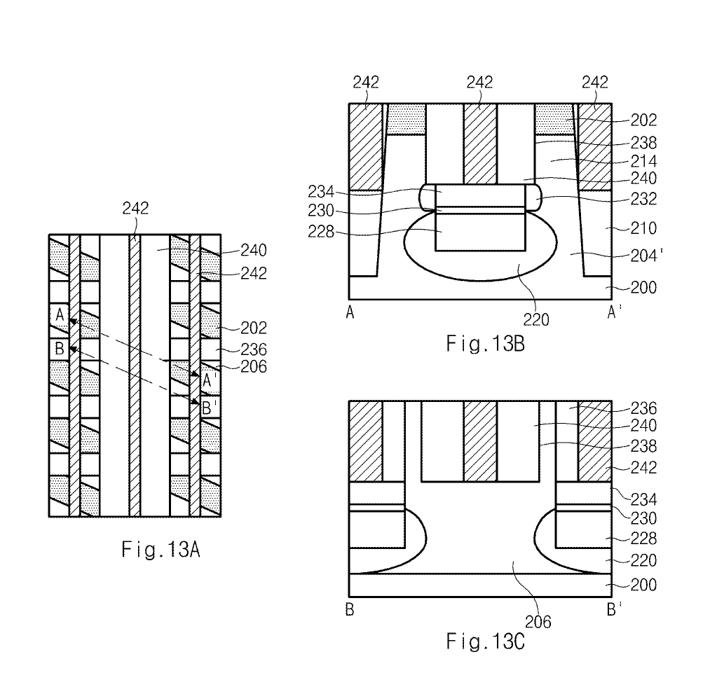

Referring to FIGS. 13A-13C, after the device isolation film 210 and the insulation film 240 are etched using a block mask so as to form a trench (not shown), the trench is filled with an insulation film, resulting in formation of a shielding film 242. In this case, the shielding film 242 may include a nitride film.

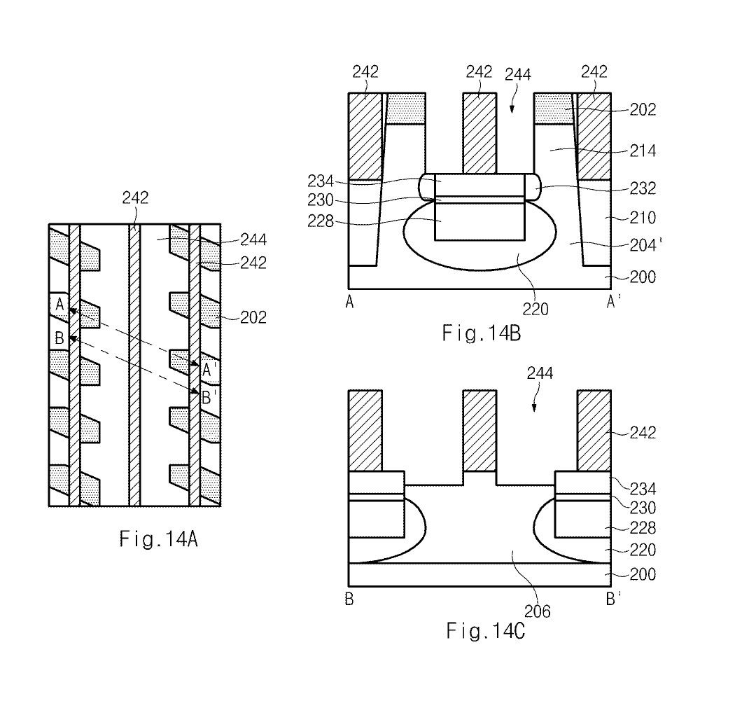

Referring to FIGS. 14A-14C, until the upper BBL 234 is exposed, a device isolation film 206 interposed between the shielding film 242 and the hard mask pattern 202, the capping insulation film 236, and the hard mask pattern 240 are etched using an etch selection ratio between the oxide film and the nitride film, resulting in formation of a trench 244. That is, the shielding film 242 including a nitride film and the hard mask pattern 202 are used as a barrier film in such a manner that the oxide films (206, 236, 240) interposed between the shielding film 242 and the hard mask pattern 202 are etched to a predetermined depth. In this case, the device isolation film 206 in which the upper BBL 234 is not formed is more deeply etched than a top surface of the upper BBL 234. That is, the device isolation film 206 interposed between the bit lines 234 is more deeply etched than the capping insulation film 236 and the insulation film 240.

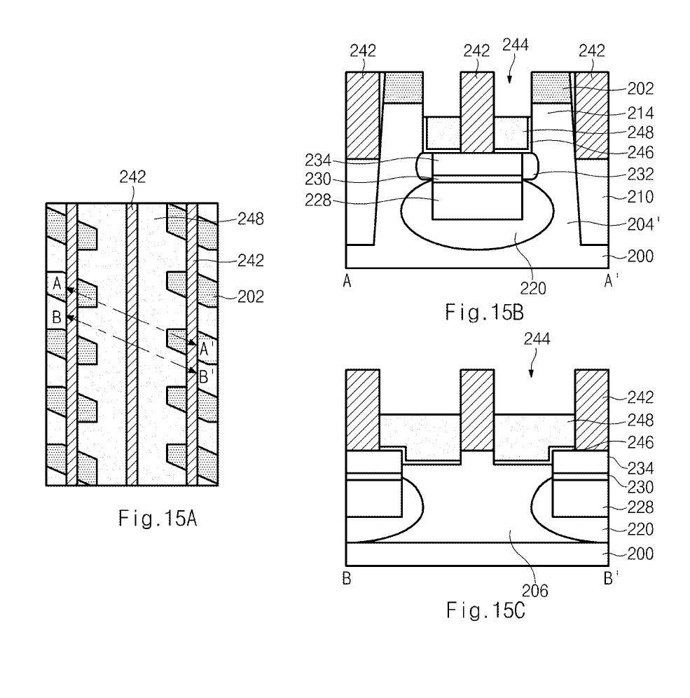

Referring to FIGS. 15A-15C, after the insulation film (gate oxide film) 246 is formed not only at a sidewall of the active pillar 214 exposed by the trench 244 but also over a surface of the upper BBL 234, a conductive film for the gate is formed to bury the trench 244. In this case, the gate conductive film may include tungsten (W).

Subsequently, the gate conductive film is planarized and etched back, such that a buried gate (word line) 248 is formed. In this case, the buried gate (BG) 248 may be formed to enclose three sides of the active pillars 214, such that an operation current can increase and operation characteristics of the semiconductor device can be improved.

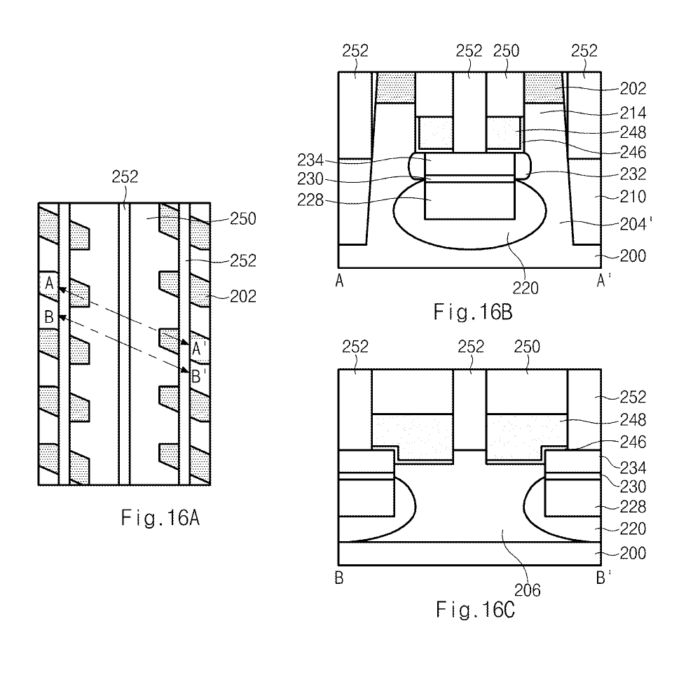

Referring to FIGS. 16A-16C, a capping insulation film 250 is formed over the buried gate (BG) 248 so as to bury the trench 244. In this case, the capping insulation film 250 may include an oxide film.

Subsequently, after the shielding film 242 is etched using a block mask employed in the process shown in FIGS. 13A-C so as to form a trench (not shown), an insulation film 252 is formed to bury the trench. Here, the insulation film 252 may include an oxide film.

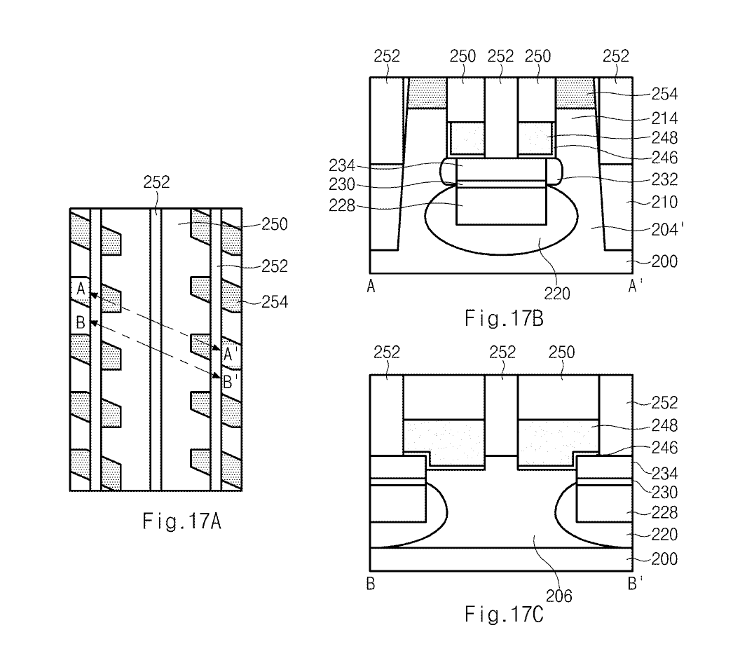

Referring to FIGS. 17A-17C, after the hard mask pattern 202 is etched using an etch selection ratio between the oxide film and the nitride film, a storage node contact (SNC) is formed in the etched region. The storage node contact (SNC) 254 may include doped polysilicon in which N-type impurity is implanted. That is, after the hard mask pattern 202 is etched using an etch selection ratio between the oxide film forming of the insulation films (250, 252) and the nitride film forming of the hard mask pattern 202, the region in which the hard mask pattern 202 is etched is buried with doped polysilicon, such that the storage node contact (SNC) 254 is formed.

Thereafter, a subsequent process for forming a capacitor coupled to the storage node contact (SNC) 254 may be carried out in the same manner as in the related art, and as such a detailed description thereof will herein be omitted for convenience of description.

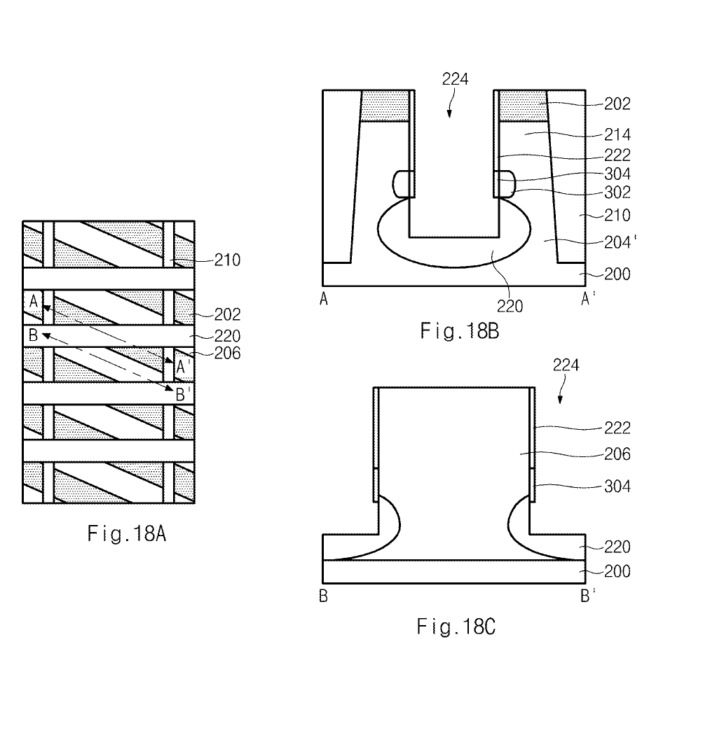

FIGS. 18A-C and 19A-C are cross-sectional views illustrating a method for forming a buried bit line (BBL) according to an embodiment. The buried bit line (BBL) shown in FIGS. 18A-C and 19A-C may be formed of a metal layer and a metal silicide film.

Referring to FIGS. 18A-C, after a trench 224 is formed by the fabrication processes shown in FIGS. 4A to 9C, a bit-line junction region 302 and a barrier metal film 304 are formed over a sidewall of the active pillar 214 where the silicon substrate is exposed.

For example, after a cobalt (Co) material is deposited over an inner surface of the trench 224, a Rapid Thermal Annealing (RTA) process is performed on the cobalt (Co) material under a nitrogen (N₂) atmosphere, such that the silicon substrate of the active pillar 214 exposed by the trench 224 reacts with the cobalt (Co) material. Accordingly, since metal ions of the cobalt (Co) material are diffused into the active pillar 214. As a result, a bit-line junction region 302 is formed. The cobalt (Co) material reacting with the silicon substrate is converted into a cobalt silicide (CoSi₂) film. Subsequently, after completion of a wet etching process, a non-reacted cobalt (Co) material is removed and only the cobalt silicide (CoSi₂) film remains, resulting in formation of a barrier metal film 304.

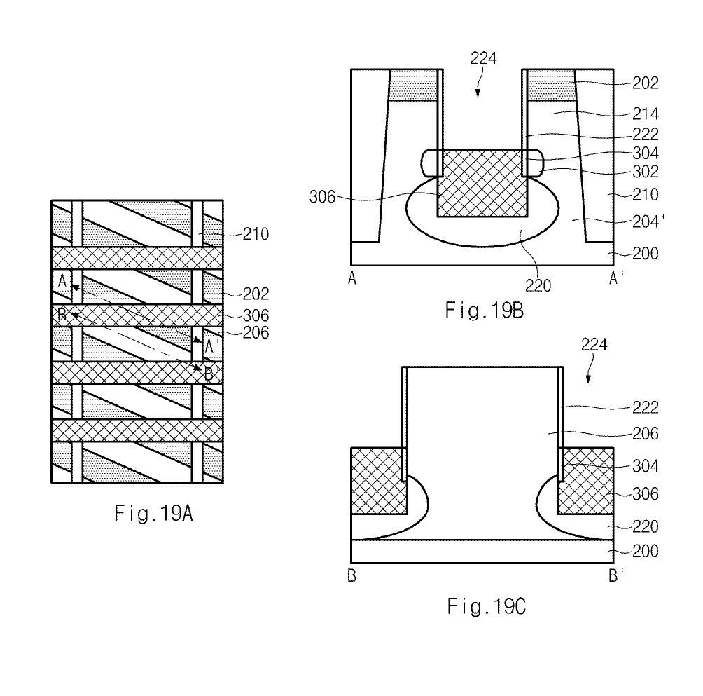

Referring to FIGS. 19A-C, a metal layer (for example, tungsten) is formed to bury the trench 224 and then etched back, resulting in formation of a buried gate 306.

Subsequent processes are identical to those of FIGS. 12A to 17C, and as such a detailed description thereof will herein be omitted for convenience of description.

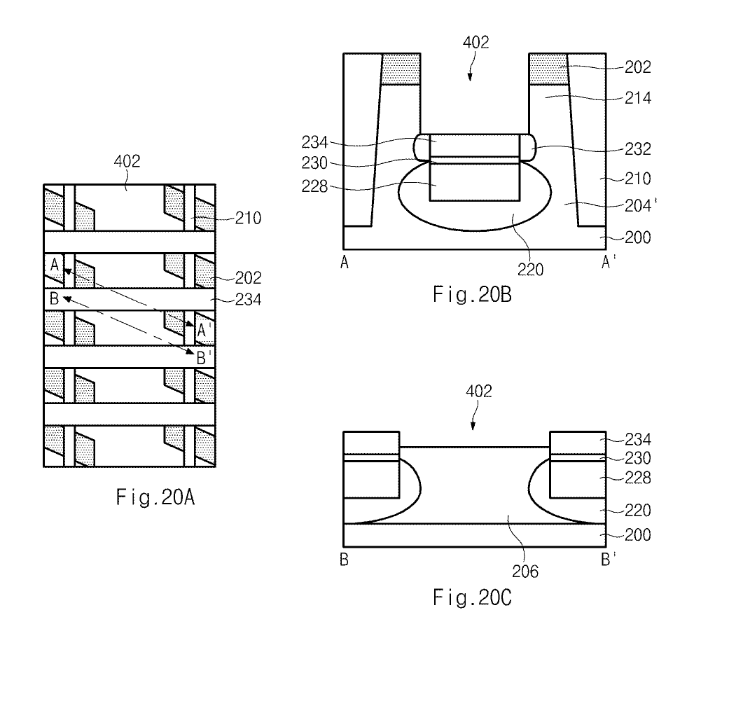

FIGS. 20A to 24C are cross-sectional views illustrating a method for forming a buried bit line (BBL) according to another embodiment.

Referring to FIGS. 20A-C, after completion of the fabrication processes of FIGS. 4A to 12C, the oxide films (206, 236, 240) between the hard mask pattern 202 and the device isolation film 210 are etched using an etch selection ratio between the nitride film and the oxide film until the upper BBL 234 is exposed, resulting in formation of a trench 402. In this case, the device isolation film 206 may be more deeply etched than the upper BBL 234.

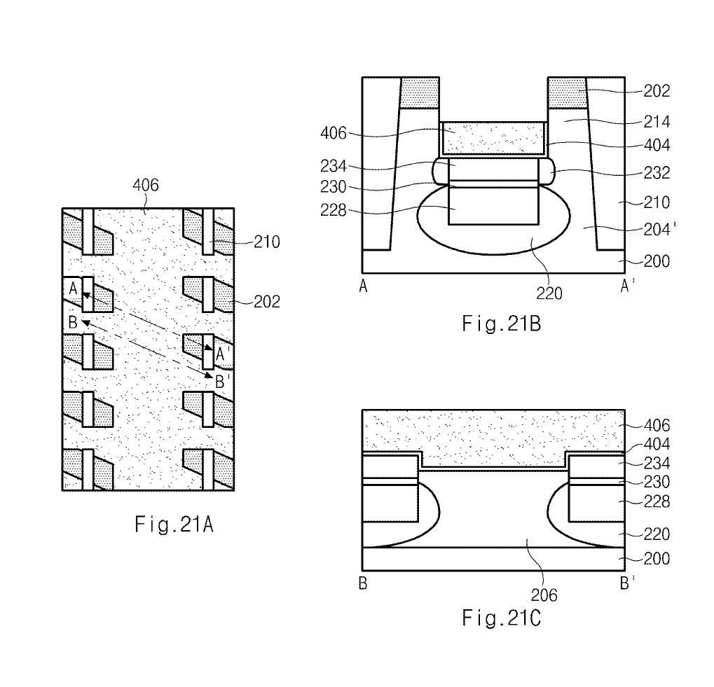

Referring to FIGS. 21A-C, an insulation film (gate oxide film) 404 is formed not only over a sidewall of the active pillar 214 exposed by the trench 402 but also over a surface of the buried bit line (BBL) 234. Subsequently, the gate conductive film 406 is formed to bury the trench 402, and is then etched back.

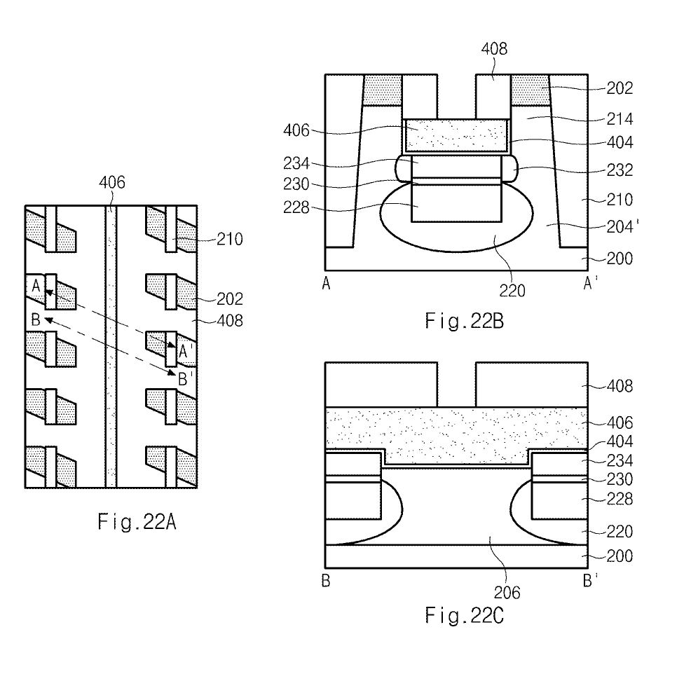

Referring to FIGS. 22A-C, an insulation film 408 for a spacer is formed over the gate conductive film 406 in such a manner that a center part of the etched-back gate conductive film 406 is exposed. In this case, the spacer insulation film 408 may include an oxide film.

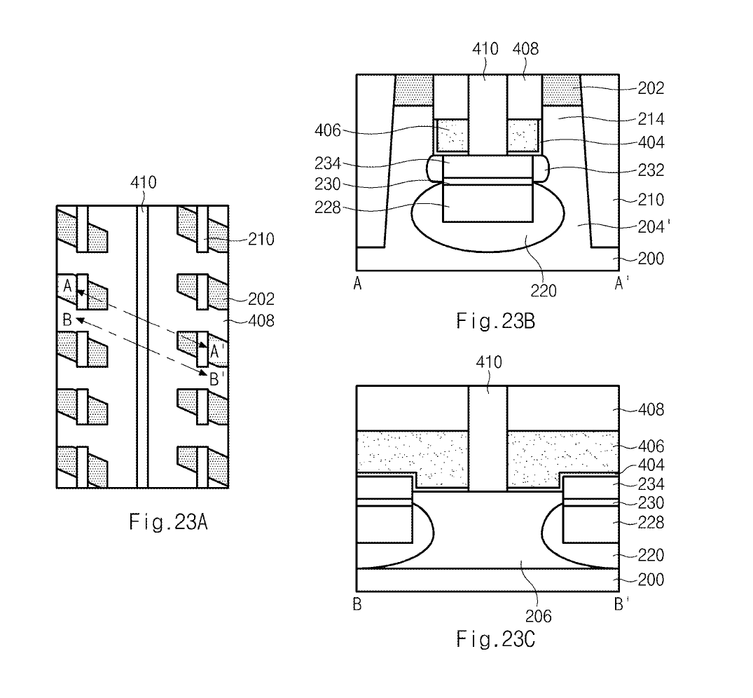

Referring to FIGS. 23A-C, the gate conductive film 406 is etched using the spacer insulation film 408 as an etch mask so that the gate conductive film 406 can be isolated. Subsequently, after an insulation film 410 is formed to be buried between the isolated gate conductive films 406 as well as to be buried between the spacer insulation films 408, the resultant insulation film 410 is planarized.

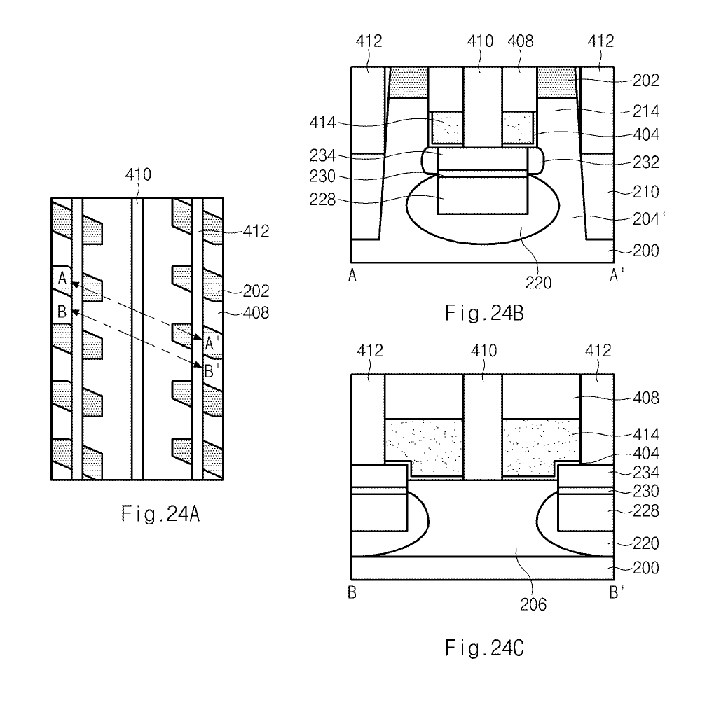

Referring to FIGS. 24A-C, after a trench (not shown) is formed by etching the device isolation film 210 and the spacer insulation film 408 using the cutting mask employed in the process shown in FIGS. 5A-C, an insulation film 412 is formed to bury the trench, resulting in formation of a buried gate (BG) 414.

Subsequently, after the hard mask pattern 202 is etched using the same method as in FIGS. 17A-C, a storage node contact (SNC) 254 (See FIG. 17B) is formed in the etched region.

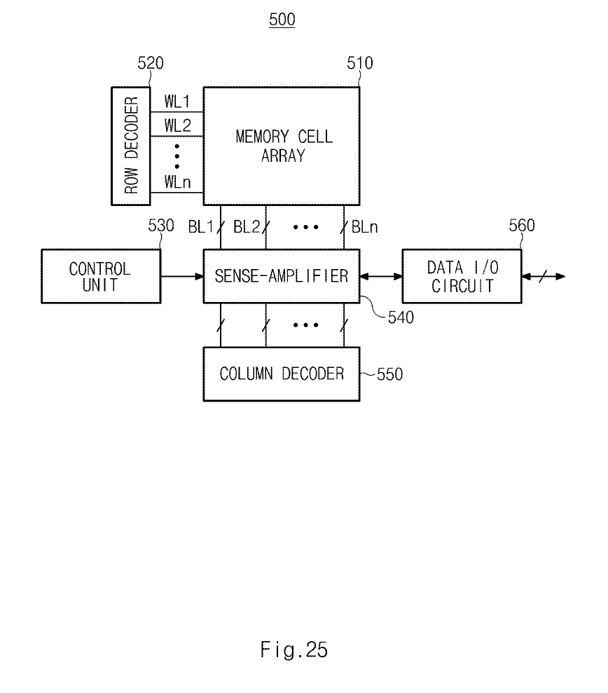

FIG. 25 is a block diagram illustrating a memory device according to an embodiment.

Referring to FIG. 25, the memory device 500 includes a memory cell array 510, a row decoder 520, a control circuit 530, a sense-amplifier (sense-amp) 540, a column decoder 550, and a data Input/Output (I/O) circuit 560.

The memory cell array 510 includes a plurality of word lines (WL1˜WLn) (where ‘n’ is a positive integer), a plurality of bit lines (BL1˜BLn), and a plurality of memory cells (not shown) interconnected between the word lines (WL1˜WLn) and the bit lines (BL1˜BLn). Here, the memory cells (not shown) are arranged in the form of a matrix. Each memory cell includes a transistor serving as a switching element that is turned on or off in response to a voltage applied to the word lines (WL1˜WLn), and each transistor includes a gate (not shown) and a source/drain region (junction region) (not shown). In this case, the word lines (WL1˜WLn) may be formed in the form of a buried gate (BG) as shown in FIGS. 1 and 2A-C. That is, the word lines (WL1˜WLn) are formed to enclose three sides of the active pillars and are buried in the silicon substrate. In addition, the bit lines (BL1˜BLn) may be formed in the form of a buried bit line (BBL) shown in FIGS. 1 and 2A-C. That is, the bit lines (BL1˜BLn) may be formed below the word lines (WL1˜WLn) and may be enclosed with the insulation film.

The row decoder 520 generates a word line selection signal (row address) for selecting a memory cell in which data is to be read or written, and outputs the word line selection signal to the word lines (WL1˜WLn) so as to select any one of the word lines (WL1˜WLn).

A control circuit 530 controls the sense-amplifier 540 in response to a control signal (not shown) received from an external part.

The sense-amplifier 540 may sense/amplify data of each memory cell, and may store data in each memory cell. In this case, the sense-amplifier 540 may include a plurality of sense-amplifiers (not shown) for sensing/amplifying data corresponding to a plurality of bit lines (BL1˜BLn), and each sense-amplifier may sense/amplify data of the plurality of bit lines (BL1˜BLn) in response to a control signal generated from the control circuit 530. The sense-amplifiers are respectively configured to sense/amplify data pieces of the bit lines (BL1˜BLn) in response to the control signal generated from the control circuit 530.

The column decoder 550 generates column selection signals for operating the sense-amplifiers coupled to cells selected by the row decoder 520, and outputs the column selection signals to the sense-amplifier 540.

The data Input/Output (I/O) circuit 560 may transmit write data received from an external part to the sense-amplifier 540 in response to a plurality of column selection signals generated from the column decoder 550, and may output read data sensed/amplified by the sense-amplifier 540 to the external part in response to the column selection signals generated from the column decoder 550.

The row decoder 520, the control circuit 530, the sense-amplifier 540, and the column decoder 550 from among the constituent elements of the above-mentioned memory device 500 may be substantially identical to those of the conventional memory device.

As described above, the above-mentioned buried gate (BG) and buried bit line (BBL) are applied to a cell array of the memory device 500, resulting in improved operation characteristics of the memory device 500.

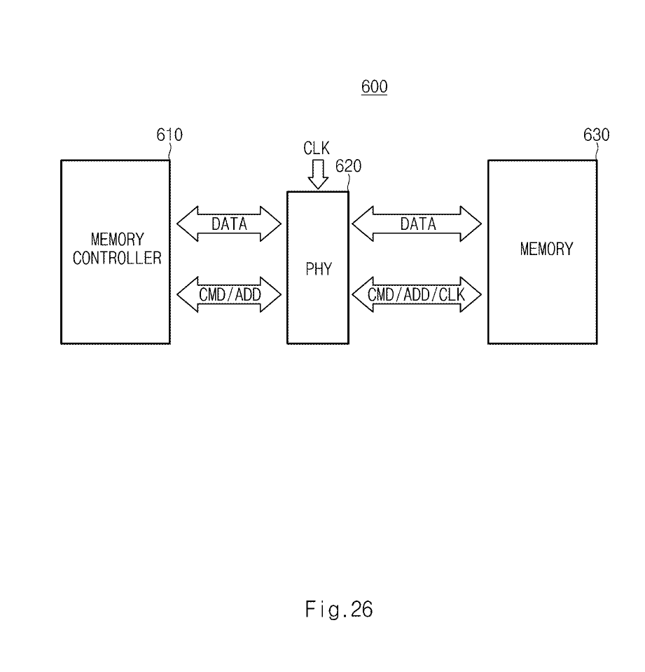

FIG. 26 is a block diagram illustrating an electronic device including a memory device according to an embodiment.

Referring to FIG. 26, the electronic device 600 may include a memory controller 610, a memory interface (PHY) 620, and a memory device 630.

The memory controller 610 generates data I/O control signals (command signal (CMD), address signal (ADD), etc.) for controlling the memory device 630, outputs the data I/O control signals to the memory device 630 through the memory interface 620, and thus controls data I/O operations (also called data Read/Write operations') of the memory device 630. The memory controller 610 may include a control unit for controlling a general data processing system to input/output data to/from the memory devices. The memory controller 610 may be embedded in a processor of electronic devices (for example, a Central Processing Unit (CPU), an Application Processor (AP), a Graphic Processing Unit (GPU), etc.), or may be configured in the form of a System on Chip (SoC) and be fabricated in one chip along with the processors. Although the memory controller 610 of FIG. 26 is denoted by one block, the memory controller 610 may include a controller of a volatile memory and a controller of a non-volatile memory.

The memory controller 610 may include a conventional controller for controlling a variety of memories. For example, the conventional controller may control Integrated Device Electronics (IDE), Serial Advanced Technology Attachment (SATA), Small Computer System Interface (SCSI), Redundant Array of Independent Disks (RAID), Solid State Disc (SSD), External SATA (eSATA), Personal Computer Memory Card International Association (PCMCIA), Multi Media Card (MMC), Embedded MMC (eMMC), Compact Flash (CF), Graphic Card, etc.

The memory interface 620 may provide a physical layer interface between the memory controller 610 and the memory device 630, and may process a timing point of data communicated between the memory controller 610 and the memory device 630 in response to a clock signal (CLK).

The memory device 630 may include a plurality of memory cells for storing data therein, store data (DATA) or read the stored data (DATA) upon receiving control signals (CMD, ADD) from the memory controller 610 through the memory interface 620, and then output the read data to the memory interface 620. In this case, the memory device 630 may include the memory device 500 shown in FIG. 25. That is, the word lines (WL1˜WLn) of the cell array of the memory device 630 may be formed to enclose three sides of the active pillars in the same manner as in the buried gate (BG) of FIGS. 1 and 2A-C, and may be buried in the silicon substrate. In addition, the bit lines (BL1˜BLn) may be formed below the word lines (WL1˜WLn) in the same manner as in a buried bit line (BBL) shown in FIGS. 1 and 2A-C, and may be enclosed with the insulation film.

The memory device 630 may include a non-volatile memory and a volatile memory. The volatile memory may include a Dynamic Random Access Memory (DRAM), a Mobile DRAM, a Static Random Access Memory (SRAM), etc. The non-volatile memory may include a Nor Flash Memory, a NAND Flash Memory, a Phase Change Random Access Memory (PRAM), a Resistive Random Access Memory (RRAM), a Spin Transfer Torque Random Access Memory (STTRAM), a Magnetic Random Access Memory (MRAM), etc. In addition, the memory device 630 shown in FIG. 26 is denoted by only one block, and may include a plurality of memory chips. If the memory device 630 is comprised of a plurality of memory chips, the memory chips may be stacked on a substrate (board) or may be mounted in a planar fashion onto the substrate (board).

As described above, the above-mentioned buried gate (BG) and buried bit line (BBL) are applied to a cell array of the memory device 630 of the electronic device 600, resulting in improved operation characteristics of the electronic device 600.

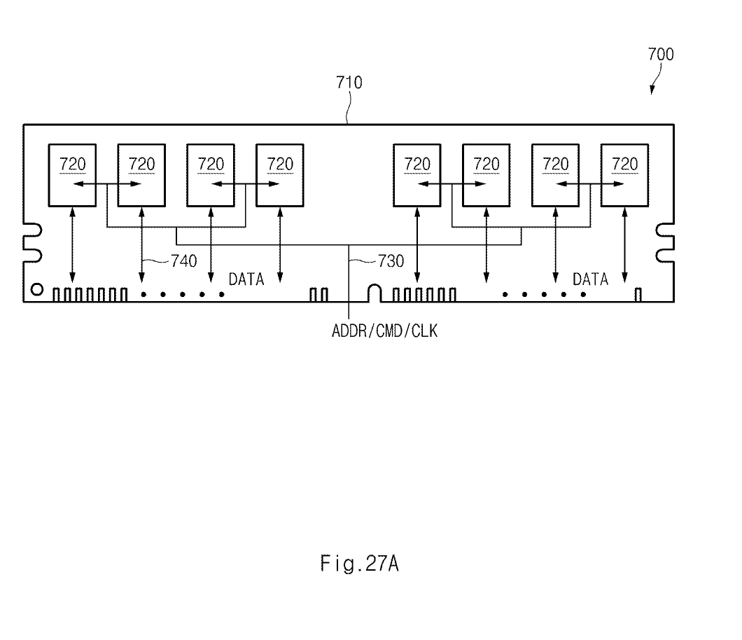

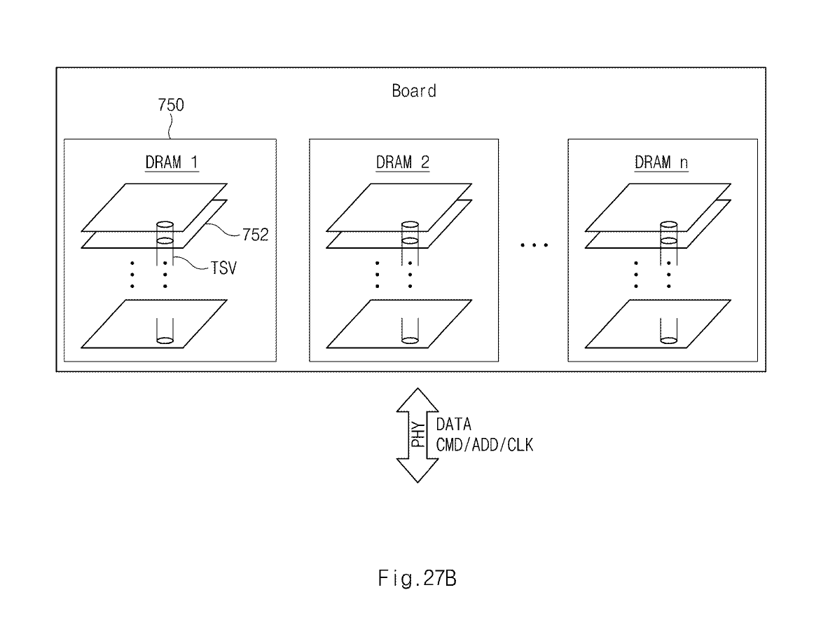

FIGS. 27A and 27B illustrate various examples of the memory device 630 shown in FIG. 26.

Referring to FIG. 27A, several memory chips 720 are mounted to a module substrate 710 in such a manner that the memory chips 720 can be inserted into memory slots of a computer.

The semiconductor module 700 includes a plurality of memory chips 720 mounted to a module substrate 710, a command link 730 for receiving signals (ADD, CMD, and CLK) controlling the memory chips 720, and a data link 740 for receiving I/O data of the memory chips 720.

In this case, each memory chip 720 may include the memory device 500 shown in FIG. 25. That is, the word lines (WL1-WLn) of the cell array of the memory chip 720 may be formed to enclose three sides of the active pillars in the same manner as in the buried gate (BG) of FIGS. 1 and 2A-C, and may be buried in the silicon substrate. In addition, the bit lines (BL1-BLn) may be formed below the word lines (WL1-WLn) in the same manner as in a buried bit line (BBL) shown in FIGS. 1 and 2, and may be enclosed with the insulation film.

Although FIG. 27A exemplarily shows that memory chips 720 are mounted only at the front surface of the module substrate 710, it should be noted that the memory chips 720 can also be mounted to a back surface of the module substrate 710 without departing from the scope of the embodiment. In this case, the number of memory chips 720 mounted to the module substrate 710 is not limited only to the example of FIG. 27A. In addition, a material and structure of the module substrate 710 are not specially limited.

FIG. 27B illustrates another example of the memory device shown in FIG. 26.

Referring to FIG. 27B, the memory device 750 may be implemented by stacking/packaging a plurality of semiconductor layers (semiconductor chips) 752, and at least one memory device 750 may be mounted to a board (substrate) and operate in response to a control signal of the memory controller 610. In this case, the memory device 750 may include a specific structure in which the same semiconductor layers (chips) are interconnected through a through silicon via (TSV), or may include another structure in which heterogeneous semiconductor layers (chips) are interconnected through a TSV. Although FIG. 27B illustrates that signal transmission between semiconductor layers is achieved through a TSV for convenience of description, the scope or spirit of the embodiment is not limited thereto, and the embodiment can also be applied to a stacking structure connecting each other with a wire bonding, an interposor or interconnect structure.

In this case, the semiconductor layer 752 may include the memory device 500 shown in FIG. 25. That is, the word lines (WL1˜WLn) of the cell array of the semiconductor layer 752 may be formed to enclose three sides of the active pillars in the same manner as in the buried gate (BG) of FIGS. 1 and 2A-C, and may be buried in the silicon substrate. In addition, the bit lines (BL1˜BLn) may be formed below the word lines (WL1˜WLn) in the same manner as in a buried bit line (BBL) shown in FIGS. 1 and 2A-C, and may be enclosed with the insulation film.

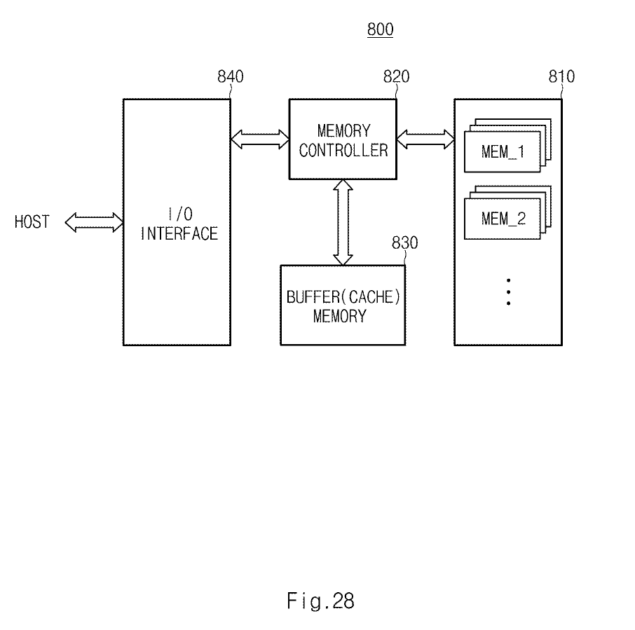

FIG. 28 is a block diagram illustrating an electronic device according to another embodiment.

Referring to FIG. 28, the electronic device 800 may include a data storage unit 810, a memory controller 820, a buffer (cache) memory 830, and an I/O interface 840.

The data storage unit 810 may store data received from the memory controller 820 upon receiving a control signal from the memory controller 820, read the stored data, and output the read data to the memory controller 820. The data storage unit 810 may include various non-volatile memory units having data to remain unchanged when powered off, for example, a Nor Flash Memory, a NAND Flash Memory, a Phase Change Random Access Memory (PRAM), a Resistive Random Access Memory (RRAM), a Spin Transfer Torque Random Access Memory (STTRAM), a Magnetic Random Access Memory (MRAM), etc.

The memory controller 820 may decode a command received from an external device (host device) through an I/O interface 840, and may control data I/O actions of the data storage unit 810 and the buffer memory 830. The memory controller 820 may include the memory controller 620 shown in FIG. 26. Although the memory controller 820 is denoted by one block as shown in FIG. 28 for convenience of description, the memory controller 820 may include a first controller for controlling a non-volatile memory 810 and a second controller for controlling the buffer memory 830 serving as a volatile memory. Here, the first controller and the second controller may be arranged independently from each other.

The buffer memory 830 may temporarily store data to be processed by the memory controller 820. In other words, the buffer memory 830 may temporarily store data to be input/output to/from the data storage unit 810. The buffer memory 830 may store data received from the memory controller 830 upon receiving a control signal from the memory controller 820, read the stored data, and output the read data to the memory controller 820. The buffer memory 830 may include a volatile memory, for example, a Dynamic Random Access Memory (DRAM), a Mobile DRAM, a Static Random Access Memory (SRAM), etc.

The I/O interface 840 may provide a physical connection between the memory controller 820 and the external device (host device), such that the I/O interface 840 may control the memory controller 820 to receive data I/O control signals from the external device as well as to exchange data with the external device. The I/O interface 840 may include at least one of various interface protocols, for example, a universal serial bus (USB) protocol, a multimedia card (MMC) protocol, a peripheral component interconnection (PCI) protocol, a PCI-express (PCI-E) protocol, a serial attached SCSI (SAS), a serial ATA (SATA) protocol, a parallel advanced technology attachment (PATA) protocol, a small computer small interface (SCSI) protocol, an enhanced small disk interface (ESDI) protocol, and an integrated drive electronics (IDE) protocol.

The word lines (WL1˜WLn) of a memory cell array of the data storage unit 810 or the buffer memory 830 for use in the electronic device 800 may be formed to enclose three sides of the active pillars in the same manner as in the buried gate (BG) of FIGS. 1 and 2A-C, and may be buried in the silicon substrate. In addition, the bit lines (BL1˜BLn) may be formed below the word lines (WL1˜WLn) in the same manner as in a buried bit line (BBL) shown in FIGS. 1 and 2A-C, and may be enclosed with the insulation film.

The electronic device 800 shown in FIG. 28 may be used as an auxiliary memory device or an external storage device of the host device. The electronic device 800 may include a Solid State Disc (SSD), a Universal Serial Bus (USB) memory, a Secure Digital (SD), a mini Secure Digital (mSD) card, a micro SD, a high-capacity Secure Digital High Capacity (SDHC), a memory stick card (MSC), a Smart Media (SM) card, a Multi Media Card (MMC), an Embedded MMC (eMMC), a Compact Flash (CF) card, etc.

As described above, the above-mentioned buried gate (BG) and buried bit line (BBL) are applied to a cell array of the buffer memory 830 of the electronic device 800, resulting in improved operation characteristics of the electronic device 800.

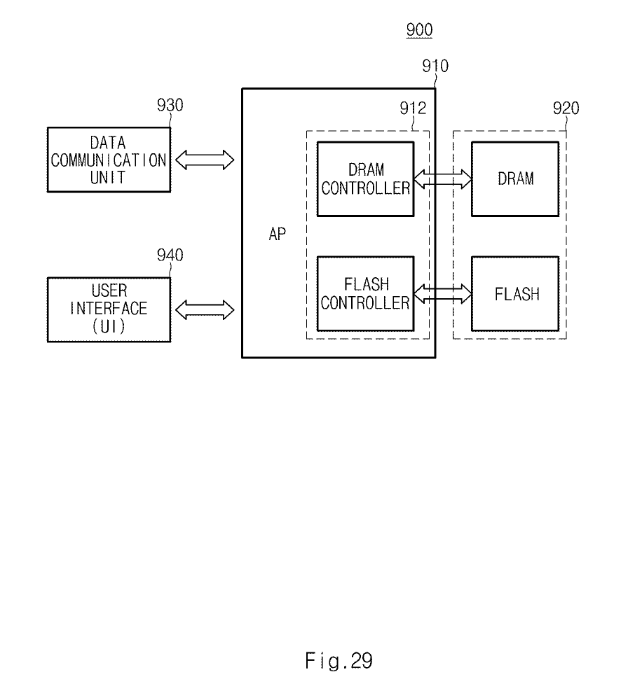

FIG. 29 is a block diagram illustrating an electronic device according to another embodiment.

Referring to FIG. 29, the electronic device 900 may include an application processor 910, a memory device 920, a data communication unit 930, and a user interface (UI) 940.

The application processor 910 may provide overall control to the electronic device 900, and may be configured to control and adjust a series of operations for processing data in response to an input command received through the user interface (UI) 940 and outputting the processed result. The application processor 910 may be implemented as a multi-core processor so as to perform multi-tasking. Specifically, the application processor 910 may include an SoC-shaped memory controller 912 for controlling data I/O operations of the memory device 920. Here, the memory controller 912 may include not only a first controller for controlling a volatile memory (for example, DRAM) but also a second controller for controlling a non-volatile memory (for example, flash memory). The memory controller 912 may include the memory controller 610 shown in FIG. 26.

Upon receiving a control signal from the memory controller 912, the memory device 920 may store data requisite for operating the electronic device 900, read the stored data, and output the read data to the memory controller 912. The memory device 920 may include a volatile memory and a non-volatile memory. Specifically, the word lines (WL1˜WLn) of a memory cell array of the memory device 920 may be formed to enclose three sides of the active pillars in the same manner as in the buried gate (BG) of FIGS. 1 and 2, and may be buried in the silicon substrate. In addition, the bit lines (BL1˜BLn) may be formed below the word lines (WL1˜WLn) in the same manner as in a buried bit line (BBL) shown in FIGS. 1 and 2A-C, and may be enclosed with the insulation film.

The data communication unit 930 may be configured to perform data communication between the application processor 910 and the external device according to a predefined communication protocol. The data communication unit 930 may include a module coupled to a wired network and a module coupled to a wireless network. The wired network module may include a Local Area Network (LAN), a Universal Serial Bus (USB), an Ethernet, a Power Line Communication (PLC), etc. The wireless network module may include Infrared Data Association (IrDA), Code Division Multiple Access (CDMA), Time Division Multiple Access (TDMA), Frequency Division Multiple Access (FDMA), Wireless LAN (WLAN), Zigbee, Ubiquitous Sensor Network (USN), Bluetooth, Radio Frequency Identification (RFID), Long Term Evolution (LTE), Near Field Communication (NFC), Wireless Broadband Internet (Wibro), High Speed Downlink Packet Access (HSDPA), Wideband CDMA (WCDMA), Ultra WideBand (UWB), etc.

The user interface (UI) 940 may provide an interface between a user and the portable electronic device 900 so that the user can input data to the portable electronic device 900. The user interface (UI) 940 may include user I/O devices for informing the user of audio or video signals indicating the processed result of the portable electronic device 900. For example, the user interface (UI) 940 may include a button, a keypad, a display (screen), a speaker, etc. incorporated into the electronic device 900.

The above-mentioned electronic device 900 may be implemented as a handheld device, for example, a mobile phone, a smartphone, a tablet computer, a personal digital assistant (PDA), an enterprise digital assistant (EDA), a digital still camera, a digital video camera, a portable multimedia player (PMP), a personal navigation device or a portable navigation device (PND), a handheld game console, or an e-book. In addition, the electronic device 900 may be implemented as an embedded system for performing a specific function of vehicles or ships.

The above-mentioned buried gate (BG) and buried bit line (BBL) are applied to a cell array of the memory device 920 for use in the electronic device 900, resulting in improved operation characteristics of the electronic device 900.

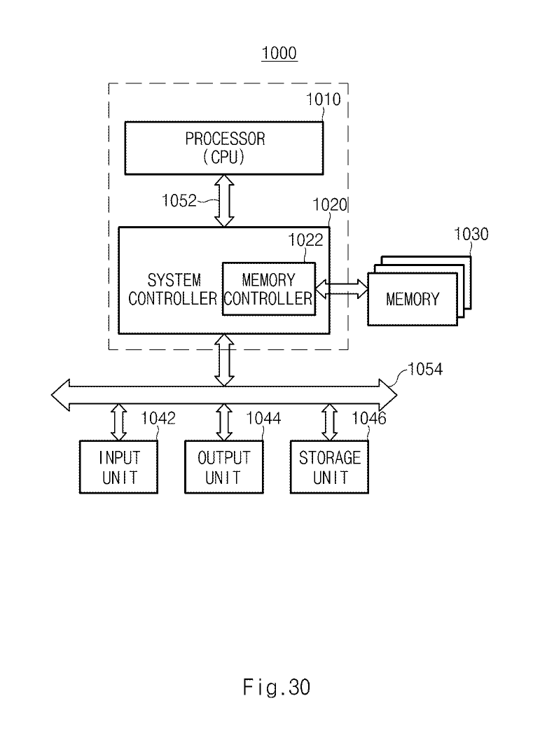

FIG. 30 is a block diagram illustrating an electronic device according to another embodiment.

Referring to FIG. 30, the electronic device 1000 may include a processor 1010 such as a CPU, a system controller 1020, and a memory device 1030. The electronic device 1000 may further include an input unit 1042, an output unit 1044, a storage unit 1046, a processor bus 1052, and an extended bus 1054.

The processor 1010 may provide overall control to the electronic device 1000, and may be configured to control and adjust a series of operations for processing (or calculating) data (or command) received through the input units 1042 and outputting the processed result to the output unit 1044. The processor 1010 may include a general Central Processing Unit (CPU) or Micro Controller Unit (MCU). The processor 1010 may be coupled to the system controller 1020 through the processor bus 1052 including an address bus, a control bus, and/or a data bus. The system controller 1020 may be coupled to the extended bus 1054 such as a Peripheral Component Interconnection (PCI). Accordingly, the processor 1010 may allow the system controller 1020 to control the input unit 1042 such as a keyboard or mouse, the output unit 1044 such as a printer or display, and the storage unit 1046 such as HDD, SSD, or CDROM. The processor 1010 may be implemented as a multi-core processor.

The system controller 1020 may control data communication between the memory device 1030 and the peripheral devices (1042, 1044, 1046) upon receiving a control signal of the processor 1010. The system controller 1020 may include a memory controller 1022 for controlling data I/O operations of the memory device 1030. In this case, the memory controller 1022 may include the memory controller 610 of FIG. 26. The system controller 1020 may include a Memory Controller Hub (MCH) and I/O Controller Hub (ICU) of Intel Corporation. Although the system controller 1020 and the processor 1010 shown in FIG. 30 are separated from each other for convenience of description, the system controller 1020 may be embedded in the processor 1010 or may be incorporated with the processor 1010 into a single SoC-shaped chip. Alternatively, only the memory controller 1022 of the system controller 1020 may be embedded in the processor 1010, or may be fabricated in the form of an SoC such that the SoC-shaped memory controller 1022 may be contained in the processor 1010.

The memory device 1030 may store data received from the memory controller 1022 upon receiving a control signal from the memory controller 1022, read the stored data, and output the read data to the memory controller 1022. The memory device 1030 may include the memory device 610 shown in FIG. 26. The word lines (WL1˜WLn) of a memory cell array of the memory device 1030 may be formed to enclose three sides of the active pillars in the same manner as in the buried gate (BG) of FIGS. 1 and 2A-C, and may be buried in the silicon substrate. In addition, the bit lines (BL1˜BLn) may be formed below the word lines (WL1˜WLn) in the same manner as in a buried bit line (BBL) shown in FIGS. 1 and 2A-C, and may be enclosed with the insulation film.

The storage unit 1046 may store data to be processed by the electronic device 1000. The storage unit 1046 may include a data storage unit embedded in the computing system or an external storage unit, and may include the memory system 800 shown in FIG. 28.

The electronic system 1000 may be any one of a variety of electronic systems operated by a variety of processes, for example, a personal computer, a server, a Personal Digital Assistant (PDA), a Portable Computer, a Web Tablet, a Wireless Phone, a mobile phone, a smart phone, a digital music player, a Portable Multimedia Player (PMP), an Enterprise Digital Assistant (EDA), a digital still camera, a digital video camera, a Global Positioning System (GPS), a voice recorder, a Telematics, an Audio Visual (AV) System, a Smart Television, other embedded systems, etc.

As described above, the above-mentioned buried gate (BG) and buried bit line (BBL) are applied to a cell array of the memory device 1030 of the electronic device 1000, resulting in improved operation characteristics of the electronic device 1000.

As is apparent from the above description, the buried bit line (BBL) according to the embodiments allows an insulation film to enclose a buried bit line (BBL) such that parasitic capacitance of the semiconductor device can be reduced. The embodiments may be applied to a semiconductor with a 6F² structure.

The above embodiments are therefore to be construed as illustrative and not restrictive.

The above embodiments are illustrative and not limitative. The embodiments are not limited by the type of deposition, etching polishing, and patterning steps described herein. Nor are the embodiments limited to any specific type of semiconductor device. For example, embodiments may be implemented in a dynamic random access memory (DRAM) device or non volatile memory device.

What is claimed is:

1. A semiconductor device comprising:
an active region defined by a device isolation film having an upper portion divided into a first active pillar and a second active pillar;
a first gate extending between the first active pillar and the second active pillar to cross the active region, the first gate coupled to the first active pillar;
a second gate extending between the first active pillar and the second active pillar to cross the active region, the second gate coupled to the second active pillar;
a conductive linepositioned under the first gate and the second gate, the conductive line commonly coupled to the first pillar and the second pillar; and
an insulation film enclosing the conductive line within the active region.

2. The semiconductor device according to claim 1,
wherein the first gate extends over three sides of the first active pillar, and
wherein the second gate extends over three sides of the second active pillar.

3. The semiconductor device according to claim 1, wherein the conductive line includes a stacked structure of a metal layer and a polysilicon layer.

4. The semiconductor device according to claim 3, wherein the insulation film encloses a bottom and sidewalls of the metal layer.

5. The semiconductor device according to claim 1, wherein the conductive line includes:
a metal layer; and
first and second metal silicide films interposed between the metal layer and respective first and second bit-line junction region.

6. The semiconductor device according to claim 1, wherein the insulation film is in a bulb shape to enclose the conductive line.

7. A semiconductor device comprising:
an active region formed to include a first active pillar and a second active pillar;
first and second gates between the first active pillar and the active pillar and arranged across the active region;
a bit line positioned under the first gate and the second gate, and arranged across the active region; and
an insulation film enclosing the bit line within the active region.

8. The semiconductor device according to claim 7, wherein the bit line is commonly coupled to the first active pillar and the second active pillar.

9. The semiconductor device according to claim 7, wherein the first gate extends over three sidewalls of the first active pillar, and the second gate extends over three sidewalls of the second active pillar.

10. The semiconductor device according to claim 7, wherein the bit line includes a stacked structure including a metal layer and a polysilicon layer.

11. The semiconductor device according to claim 10, wherein the insulation film encloses a bottom and sidewalls of the metal layer.

12. The semiconductor device according to claim 7, wherein the bit line includes:
a metal layer; and
first and second metal silicide film interposed between the metal layer and respective first and second bit-line junction regions.

13. The semiconductor device according to claim 7, wherein the first gate and the second gate extend over sidewall of the bit line.

14. The semiconductor device according to claim 7, wherein the insulation film is formed as a bulb shape and encloses the bit line.

15. The semiconductor device according to claim 14, wherein the insulation film does not extend over a bit-line junction region.

16. The semiconductor device according to claim 7, further comprising: an air-gap interposed between the bit lines.

17. An electronic device comprising:
a memory device configured to store data and read the stored data in response to a data input/output (I/O) control signal; and
a memory controller configured to generate the data I/O control signal, and control data I/O operations of the memory device,
wherein the memory device includes:
an active region including a first active pillar and a second active pillar;
first and second gates extending between the first active pillar and the active pillar and across the active region;
a conductive line positioned under the first gate and the second gate, and arranged across the active region; and
an insulation film enclosing the conductive line within the active region.

18. The electronic device according to claim 17, further comprising:
a processor configured to store data in the memory device by controlling the memory controller, and to perform calculation corresponding to an external input command using data stored in the memory device.
